(19) United States
(12) Patent Application Publication
(10) Pub. No.: US 2026/0150270 A1
(43) Pub. Date: May 28, 2026

(54) MEMORY DEVICES AND FABRICATING METHODS THEREOF

(71) Applicant: Yangtze Memory Technologies Co., Ltd., Wuhan (CN)

(72) Inventors: Zongliang Huo, Wuhan (CN); Wei Xu, Wuhan (CN); Fan Gong, Wuhan (CN); Bin Yuan, Wuhan (CN); Qiangwei Zhang, Wuhan (CN)

(21) Appl. No.: 19/016,894

(22) Filed: Jan. 10, 2025

(30) Foreign Application Priority Data
Nov. 27, 2024 (WO) PCT/CN2024/134870
Dec. 6, 2024 (CN) 202411799486.X

(51) Int. Cl. H10B 12/00

(52) U.S. Cl. CPC H10B 12/485; H10B 12/0335; H10B 12/315; H10B 12/482; H10B 12/488

(57) ABSTRACT

A memory device includes an array of memory cells in an array region and bit lines coupled with the memory cells in the array. The array includes a first sub-array and a second sub-array, and the bit lines extend in a bit line direction. The memory device further includes contact structures in a first connecting region and isolation walls. The contact structures are located between the first sub-array and the second sub-array, and the isolation walls are between the contact structures and the first sub-array, and between the contact structures and the second sub-array.

### CROSS-REFERENCE TO RELATED APPLICATIONS

This application claims the benefit of priorities to International Application No. PCT/CN 2024/134870, filed on Nov. 27, 2024, and Chinse Application No. 202411799486.X, filed on Dec. 6, 2024, both of which are incorporated herein by reference in their entireties.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

One aspect of the present disclosure provides a memory device includes an array of memory cells in an array region and bit lines coupled with the memory cells in the array. The array includes a first sub-array and a second sub-array, and the bit lines extend in a bit line direction. The memory device further includes contact structures in a first connecting region and isolation walls. The contact structures are located between the first sub-array and the second sub-array, and the isolation walls are between the contact structures and the first sub-array, and between the contact structures and the second sub-array.

In some implementations, the first connecting region includes a stacked-structure in a channel direction, the channel direction is perpendicular to the bit line direction. The stacked-structure includes a first dielectric layer, a second dielectric layer covering the first dielectric layer, and a third dielectric layer covering the second dielectric layer. A material of the second dielectric layer is different from a material of the first dielectric layer and the third dielectric layer.

In some implementations, the contact structures are aligned on a same line along a word line direction, the word line direction is perpendicular to the bit line direction and the channel direction.

In some implementations, the contact structures in a first row along a word line direction are staggered with contact structures in a second row along the word line direction, the word line direction is perpendicular to the bit line direction and the channel direction.

In some implementations, the memory device further includes contact structures in a second connecting region located at a first edge of the array of memory cells. The second connecting region is away from the first connecting region.

In some implementations, the memory device further includes contact structures in a third connecting region located at a second edge of a first array of memory cells opposite to the first edge. The first connecting region is located between the second connecting region and the third connecting region.

In some implementations, the array of memory cells includes a plurality of transistors and a plurality of capacitors coupled with the transistors. The contact structures and the capacitors of the memory cells are located in the stacked-structure, and a size of the contact structures surrounded by the stacked-structure along the channel direction equals to a size of the capacitors surrounded by the stacked-structure along the channel direction.

In some implementations, along the bit line direction, bit lines coupled to transistors in a first array of memory cells are truncated from bit lines coupled to transistors in a second array of memory cells by a dielectric structure.

In some implementations, memory device further includes a plurality of conductive pillars aligned with the dielectric structure in the channel direction, and the conductive pillars contact with the dielectric structure.

In some implementations, along the bit line direction, each bit line connects to a first row of transistors in the first sub-array of memory cells and a corresponding second row of transistors in the second sub-array of memory cells.

In some implementations, along the bit line direction, capacitors in the first sub-array of memory cells and capacitors in the second sub-array of memory cells are separated by the isolation walls and contact structures located between the isolation walls.

In some implementations, the memory device further includes semiconductor structures located between the first sub-array and the second sub-array. The semiconductor structures are covered by the isolation walls and the contact structures are located between the isolation walls. The semiconductor structures are doped as either N-type or P-type.

In some implementations, a cross-section of the isolation walls on a first plane include a plurality of enclosed structures, the first plane is perpendicular to the channel direction. The contact structures are located outside the enclosed structures.

In some implementations, capacitors in the first sub-array of memory cells are surrounded by a first enclosed structure of the isolation walls, and capacitors in the second sub-array of memory cells are surrounded by a second enclosed structure of the isolation walls.

Another aspect of the present disclosure provides a method of forming a memory device. The method includes forming an array of transistors on a substrate; forming bit lines coupled with the transistors in the array and extending in a bit line direction; forming a stacked-structure on the array of transistors; forming an array of holes throughout the stacked-structure; and forming contact structures coupled with the bit lines in a first group of the holes and capacitors coupled with the transistors in a second group of the holes. The contact structures are isolated from the capacitors by isolation walls.

In some implementations, forming a stacked-structure covering the array of transistors includes: forming a first dielectric layer on the array of transistors; forming a second dielectric layer on the first dielectric layer; and forming a third dielectric layer on the second dielectric layer. A material of the second dielectric layer is different from a material of the first dielectric layer or a material of the third dielectric layer.

In some implementations, forming an array of holes throughout the stacked-structure includes filling the array of holes with a sacrifice material different from the material of the first dielectric layer, the material of the second dielectric layer, and the material of the third dielectric layer.

In some implementations, forming the contact structures and the capacitors includes forming a first mask on the stacked-structure to cover the first group of holes and the second group of holes, and removing the sacrifice material in a third group of holes that are exposed from openings on the first mask.

In some implementations, the third group of holes includes a plurality of enclosed structures, the first group of holes are located between two adjacent enclosed structures, and the second group of holes are located within the plurality of enclosed structures.

In some implementations, forming the contact structures and the capacitors further includes expanding the third group of holes by removing the second dielectric layer surrounding the third group of holes to punch the holes in the third group and form at least one isolation trench.

In some implementations, forming the contact structures and the capacitors further includes forming the isolation walls in the at least one isolation trench by depositing a dielectric material in the isolation trench, and the dielectric material is different from the material of the second dielectric layer.

In some implementations, forming the contact structures and the capacitors further includes forming the contact structures in the first group of holes by replacing the sacrifice material in the first group of holes with a conductive material, at least part of the contact structures being coupled with the bit lines.

In some implementations, forming the contact structures and the capacitors further includes forming first electrodes of the capacitors in the second group of holes by replacing the sacrifice material in the second group of holes with a conductive material. The first electrodes are coupled with the transistors, and the first electrodes are formed in a same fabrication process as the contact structures.

In some implementations, wherein a size of the contact structures surrounded by the stacked-structure along the channel direction equals to a size of the first electrodes surrounded by the stacked-structure along the channel direction.

In some implementations, a size of the contact structures equals a size of the first electrodes of the capacitors.

In some implementations, forming the contact structures and the capacitors further includes removing the second dielectric layer surrounding the first electrodes of the capacitors to form a plurality of cavities; forming a dielectric layer surrounding the first electrodes, and filling the plurality of cavities with a conductive material to form second electrodes of the capacitors.

Another aspect of the present disclosure provides a memory device including an array of memory cells in an array region surrounded by an enclosed isolation wall, bit lines coupled with the memory cells in the array and extending in a bit line direction, and contact structures located in a connecting region outside the enclosed isolation wall. The array of memory cells includes a plurality of transistors and a plurality of capacitors coupled with the transistors, and the contact structures and the capacitors of the memory cells have a same size along the channel direction.

In some implementations, each capacitor of the capacitors of the memory cells includes a first electrode coupled with a corresponding transistor, a dielectric layer surrounding the first electrode, and a second electrode surrounding the dielectric layer and coupled to a common electrode. A size of the contact structures equals a size of the first electrodes of the capacitors.

In some implementations, the connecting region includes a stacked-structure in a channel direction, the channel direction is perpendicular to the bit line direction. The stacked-structure includes a first dielectric layer, a second dielectric layer covering the first dielectric layer and a third dielectric layer covering the second dielectric layer. A material of the second dielectric layer is different from a material of the first dielectric layer and the second dielectric layer.

In some implementations, the contact structures are aligned on a same line on an edge of the array of memory cells along a word line direction, the word line direction is perpendicular to the bit line direction and the channel direction.

In some implementations, the contact structures in a first row on an edge of the array of memory cells are staggered with contact structures in a second row on an opposite edge of the array of memory cells along a word line direction, the word line direction is perpendicular to the bit line direction and the channel direction.

In some implementations, the array of memory cells includes a plurality of transistors and a plurality of capacitors coupled with the transistors. The contact structures and the capacitors of the memory cells are located in the stacked-structure, a size of the contact structures surrounded by the stacked-structure along the channel direction equals to a size of the capacitors surrounded by the stacked-structure along the channel direction.

In some implementations, along the bit line direction, bit lines coupled to transistors in a first array of memory cells are truncated from bit lines coupled to transistors in a second array of memory cells by a dielectric structure.

In some implementations, the dielectric structure is covered by the connecting region.

In some implementations, along the bit line direction, capacitors in a first array of memory cells are truncated from capacitors in a second array of memory cells by the connecting region located between the first array of memory cells and the second array of memory cells.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells each having a vertical transistor and a storage unit, according to some implementations of the present disclosure.

FIG. 2 illustrates a schematic plan view of a memory device, according to some implementations of the present disclosure.

FIG. 3A illustrates a schematic plan view of a memory device, according to some implementations of the present disclosure.

FIG. 3B illustrates a schematic side cross-sectional view of a cross-section of a portion of the memory device in FIG. 3A.

FIG. 3C illustrates a schematic plan view of a memory device, according to some implementations of the present disclosure.

FIG. 4A illustrates a schematic plan view of a memory device, according to some implementations of the present disclosure.

FIG. 4B illustrates a schematic side cross-sectional view of a cross-section of a portion of the memory device in FIG. 4A.

FIG. 4C illustrates a schematic plan view of a memory device, according to some implementations of the present disclosure.

FIG. 5A illustrates a schematic plan view of a memory device, according to some implementations of the present disclosure.

FIG. 5B illustrates a schematic side cross-sectional view of a cross-section of a portion of the memory device in FIG. 5A.

FIG. 6 illustrates a flowchart of a fabricating method for forming a memory device, according to some implementations of the present disclosure.

FIGS. 7A-7W each illustrates a schematic side cross-sectional view of a 3D memory device at a certain fabricating stage of the method shown in FIG. 6, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors serve as the switching or selection devices within the memory cells of some memory technologies, such as Dynamic Random Access Memory (DRAM). In a one-transistor-one-capacitor (1T1C) DRAM architecture, data is stored in the capacitors. In conventional DRAM designs, the bit lines (BL) are typically positioned in a lower layer beneath both the transistors and the capacitors, resulting in significant parasitic capacitance between the bit lines. Moreover, the routing interconnections for the bit lines are generally situated on both sides of the array. The Back-End-of-Line (BEOL) routing further contributes to this parasitic capacitance. To satisfy the requirements for sense margin, the capacitors must possess a substantially large capacitance, which presents considerable challenges in terms of process complexity and complicates further miniaturization efforts as DRAM technology continues to scale.

To address one or more of the issues identified above, the present disclosure proposes a solution that employs a full print fabrication process. Specifically, bit lines are integrated through contact structures that are formed concurrently with the capacitors of the memory array. In some implementations, a plurality of conductive pillars are positioned within the center of each memory array, serving as contact structures for the bit lines. In some other implementations, additional conductive pillars may be provided at the edges of each memory array, functioning as contact structures for the bit lines as well. The introduction of these conductive pillars allows for the integration of the contact structures into the memory array's capacitors, significantly reducing both the area occupied by the contact structures and the parasitic capacitance between the bit lines. Importantly, this approach does not incur additional costs, as the conductive pillars are formed during the same fabrication process as the primary capacitors. In some implementations of the present disclosure, the memory array is provided with isolation walls situated between the contact structures and the capacitors, which further mitigates parasitic capacitance.

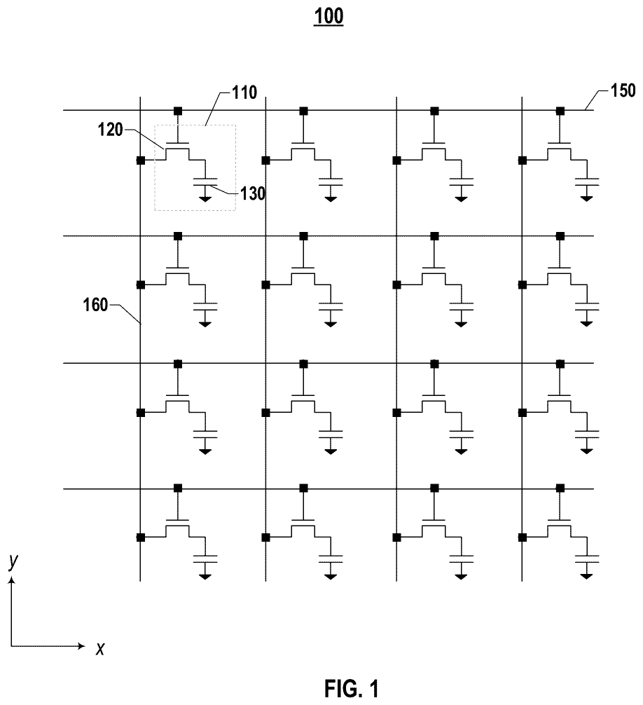

FIG. 1 illustrates a schematic diagram of a memory device 100 having an array of memory cells each having a vertical transistor, according to some implementations of the present disclosure. Memory device 100 can include a memory cell array in which each memory cell 110 includes a vertical transistor 120 and a storage unit coupled to vertical transistor 120. In some implementations as shown in FIG. 1, the memory cell array is a DRAM cell array, and the storage unit is a capacitor 130 for storing charge as the binary information stored by the respective DRAM cell. In some other implementations not shown in the figures, the memory cell array is a PCM cell array, and the storage unit can be a PCM element (e.g., including chalcogenide alloys) for storing binary information of the respective PCM cell based on the different resistivities of the PCM element in the amorphous phase and the crystalline phase.

As shown in FIG. 1, memory cells 110 can be arranged in a two-dimensional (2D) array having rows and columns. Memory device 100 can include word lines 150 coupling the memory cell array to peripheral circuits for controlling the switch of transistors 120 in memory cells 110 located in a row, as well as bit lines 160 coupling the memory cell array to peripheral circuits for sending data to and/or receiving data from memory cells 110 located in a column. That is, each word line 150 is coupled to a respective row of memory cells 110, and each bit line 160 is coupled to one or more respective logic columns of memory cells 110. In some implementations, the gate of vertical transistor 120 is coupled to word line 150, one of the source and the drain of vertical transistor 120 is coupled to bit line 160, the other one of the source and the drain of vertical transistor 120 is coupled to one electrode of capacitor 130, and the other electrode of capacitor 130 is coupled to the ground.

Consistent with the scope of the present disclosure, transistors 120, such as vertical metal-oxide-semiconductor field-effect transistors (MOSFETs), can replace the conventional planar transistors as the pass transistors of memory cells 110 to reduce the area occupied by the pass transistors, the coupling capacitance, as well as the interconnect routing complexity, as described below in detail.

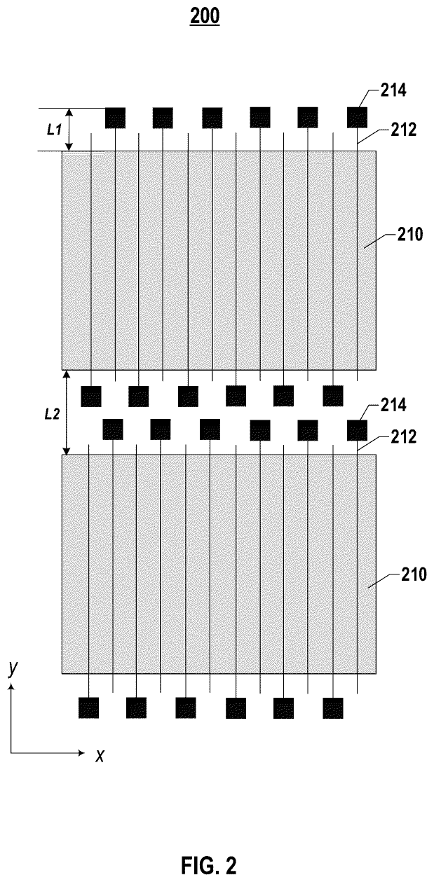

FIG. 2 illustrates a schematic plan view of a memory device 200 including a plurality of memory arrays 210 in the x-y plane, according to some implementations of the present disclosure. Each memory array 210 can include an array of memory cells each including a vertical transistor and a vertical capacitor. The vertical transistor can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 2, each memory array 210 can include a plurality of bit lines 212 each extending in a word line direction (the y-direction, referred to as the bit line direction). It is noted that, each memory array 210 can further include a plurality of word lines (not shown) each extending in a bit line direction (the x-direction, referred to as the word line direction) perpendicular to the word line direction. The word lines and bit lines 212 may be formed in different lateral planes for ease of routing. In some implementations, memory device 200 can further include a plurality of bit line contact structures 214 located at both sides of each memory array 210 along the bit line direction (the y-direction). Bit lines 212 can be interconnected to the bit line contact structures 214 in a staggered manner at both sides of each memory array 210 along the bit line direction (the y-direction). For example, a first group of bit line contact structures 214 located at a first side of each memory array 210 can be connected to the odd numbers of bit lines 212, and a second group of bit line contact structures 214 located at a second side of each memory array 210 can be connected to the even numbers of bit lines 212. It should be noted that in some implementations, there is an angle between the bit line direction and the x-direction, and there is also an angle between the word line direction and the y-direction. In other words, the bit line direction is not perpendicular to the word line direction and an angle between them may be greater than or less than 90 degrees. For example, in some implementations, the angle between the bit line direction and the word line direction may be, but not limited to, 70°, 76°, 80°, 89°, 93°, 101°, 115°, 117°, and the like.

Such a layout may require a relatively large space between adjacent memory arrays 210 to locate bit line contact structure 214. For example, a first distance L1 between a first row of bit line contact structures 214 and an edge of memory array 210 is 530 nm in certain semiconductor structures, and a second distance between two adjacent memory arrays 210 L2 is more than twice of a first distance L1, which can be 1210 nm. The region between adjacent memory arrays 210 for locating the bit line contact structures 214 can occupy approximately 5% of the total area of the memory device, making it difficult to downsize the memory arrays 210 because this proportion increases when downsizing the memory arrays 210. Further, due to the bit lines 212 being driven via the bit line contact structures 214 on both ends, the lead-out resistance of the bit lines 212 can be relatively high, resulting in substantial resistive-capacitive (RC) delay. Additionally, the wiring of the bit line driving wires contributes significantly to parasitic capacitance due to being driven on both ends.

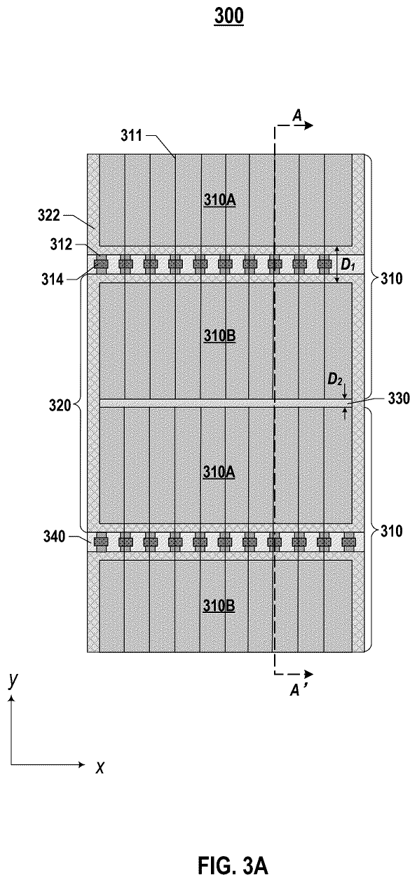

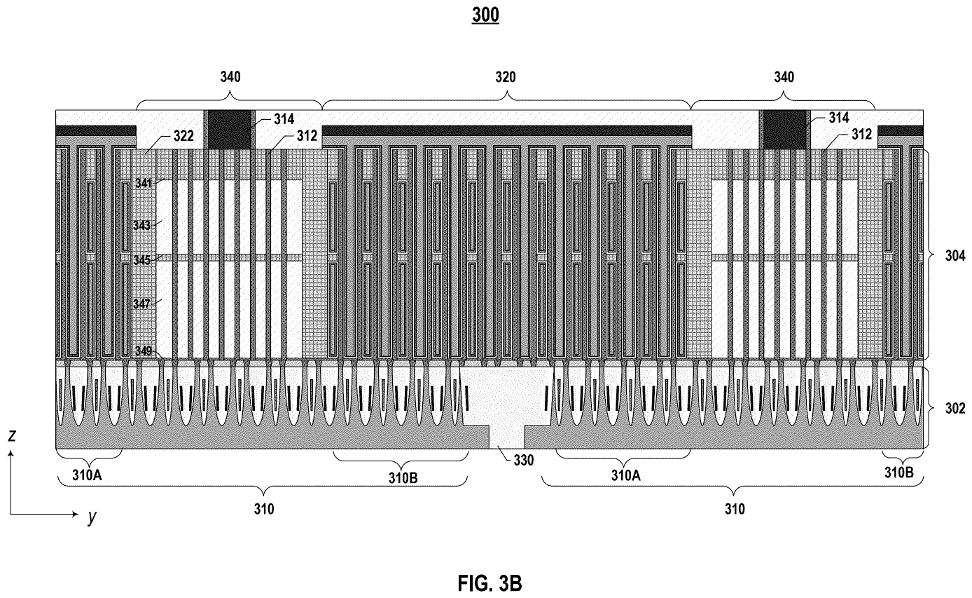

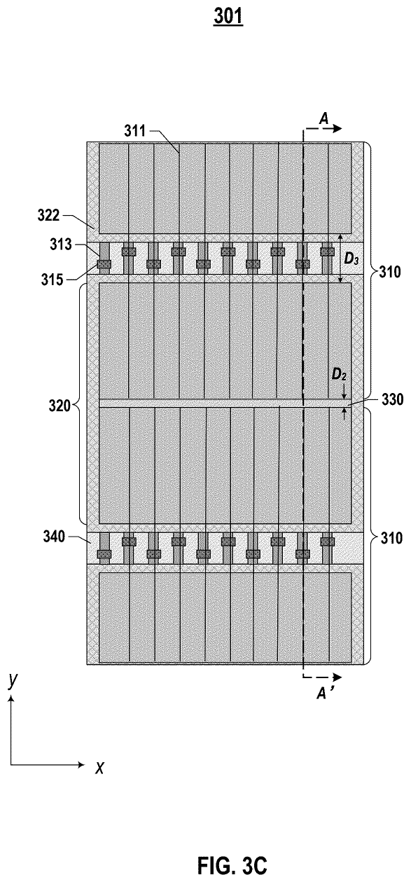

FIG. 3A illustrates a schematic plan view of a memory device 300 including a plurality of memory arrays 310 in the x-y plane, FIG. 3B is a cross-sectional view of memory device 300 in FIG. 3A along AA′ direction, FIG. 3C illustrates a schematic plan view of a memory device 301 including a plurality of memory arrays 310 in the x-y plane, according to some implementations of the present disclosure. Each memory array 310 can include an array of memory cells each including a vertical transistor 302 and a vertical capacitor 304. Vertical transistor 302 can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 3A, each memory array 310 can include a plurality of bit lines 311 each extending in the bit line direction (the y-direction). It is noted that, each memory array 310 can further include a plurality of word lines (not shown) each extending in the word line direction (the x-direction). The word lines and bit lines 311 may be formed in different lateral planes for ease of routing. In some implementations, each memory array 310 can further include a first sub-array 310A and a second sub-array 310B, and memory device 300 can further include a plurality of bit line contact structures 312 coupled with the bit lines 311. The bit line contact structures 312 are formed in a first connecting region 340 located between first sub-array 310A and second sub-array 310B, as shown in FIGS. 3A and 3B.

Referring to FIG. 3B, first connecting region 340 aligns with vertical capacitors 304 in all lateral directions. In some implementations, bit line contact structures 312 have a same height with vertical capacitors 304. In some implementations, first connecting region 340 can include a stacked-structure in a channel direction (the z-direction). For instance, as shown in FIG. 3B, the stacked-structure includes a first layer 341, a second layer 343, a third layer 345, a fourth layer 347, and fifth layer 349. In some implementations, all the five layers of the stacked-structure are dielectric layers including, but not limited to, silicon oxide, silicon nitride, silicon oxynitride, low-k dielectrics, or any combination thereof. In some implementations, the materials of any two adjacent dielectric layers are different. For example, first layer 341, third layer 345, and fifth layer 349 are formed by silicon oxide, and second layer 343 and fourth layer 347 are formed by silicon nitride. It should be noted that in some implementations, there is an angle between the channel direction and the z-direction. In other words, the channel direction is not perpendicular to the first and word line directions. A first angle between the channel direction and the bit line direction and a second angle between the channel direction and the word line direction may be greater than or less than 90 degrees. For example, in some implementations, the first angle and the second angle may be, but not limited to, 70°, 76°, 80°, 89°, 93°, 101°, 115°, 117°, and the like.

In some implementations, along the bit line direction (the y-direction), bit lines 311 coupled to transistors 302 in a first array of memory arrays 310 are truncated from bit lines 311 coupled to transistors 302 in a second array of memory arrays 310 by a dielectric structure 330, as shown in FIGS. 3A and 3B. Vertical capacitors 304 aligned with dielectric structure 330 in the channel direction (the z-direction) are conductive pillars as they do not connect to any transistors. In some implementations, along the bit line direction (the y-direction), transistors 302 in first sub-array 310A share bit lines with corresponding transistors 302 in second sub-array 310B. That is, vertical capacitors 304 in first sub-array 310A and second sub-array 310B share a same set of bit lines 311, and bit line contact structures 312 are located at the middle of bit lines 311, as shown in FIG. 3A.

In some implementations, along the bit line direction (the y-direction), vertical capacitors 304 in first sub-array 310A and vertical capacitors 304 in second sub-array 310B are separated by at least two isolation walls 322, and bit line contact structures 312 are located between the at least two isolation walls 322. For example, as shown in FIG. 3A, a first isolation wall 322 is formed between first sub-array 310A and connecting region 340 to separate the memory cells in first sub-array 310A from bit line contact structures 312 in connecting region 340. A second isolation wall 322 is formed between second sub-array 310B and connecting region 340 to separate the memory cells in second sub-array 310B from bit line contact structures 312 in connecting region 340. A parasite capacitance of the bit line contact structures 312 are greatly reduced by isolation walls 322. In some implementations, vertical capacitors 304 covered by isolation walls 322 and bit line contact structures 312 located between isolation walls 322 are dummy transistors as they are not connected with any vertical capacitors 304. In some implementations, the dummy transistors have a same structure with transistors 302, except for a semiconductor body of the dummy transistor is doped differently. For example, each dummy transistors includes a semiconductor body and a gate structure coupled with the semiconductor body, and the semiconductor body is doped as N-type or P-type, such that no PN junction will be formed in the semiconductor body and the dummy transistors serve as a conductive layer to couple the bit line with transistors 302. It should be noted that the number of vertical capacitors 304, the number of bit line contact structures 312, and the number of transistors 302 in the figures of the present disclosure are illustrative and should not be read as limitations of the present disclosure.

In some implementations, isolation walls 322 can include a plurality of enclosed structures 320. For example, as shown in FIGS. 3A-3C, isolation walls 322 include a first enclosed structure 320 with a rectangular shape. Bit line contact structures 312 are located between two adjacent enclosed structures 320. Vertical capacitors 304 enclosed by a first enclosed structure 320 form a capacitor array including vertical capacitors 304 in second sub-array 310B of the first memory array and vertical capacitors 404 in first sub-array 310A of the second memory array. As shown in FIGS. 3A and 3C, vertical capacitors 304 in first sub-array 310A are surrounded by first enclosed structure 320, and vertical capacitors 304 in second sub-array 310B are surrounded by a second enclosed structure.

In some implementations, the plurality of bit line contact structures 312 can further include a plurality of bit line pick-up nodes 314 correspondingly. Referring to FIG. 3B, bit line pick-up nodes 314 are formed on bit line contact structures 312 and are configured to connect bit lines 311 with contacts of an interconnect layer. Each bit line pick-up node 314 contacts with at least one bit line contact structures 312. In some implementations, bit line pick-up node 314 can pick up bit lines 311 by connecting any one of bit line contact structures 312 because each bit line 311 is connected to a plurality of bit line contact structures 312, as shown in FIG. 3B.

Referring to FIG. 3C, a memory device 301 including a plurality of memory arrays 310 in the x-y plane is provided. Each memory array 310 includes a first sub-array 310A and a second sub-array 310B, and memory device 301 can further include a plurality of bit line contact structures 313 coupled with the bit lines 311. The bit line contact structures 313 are formed in first connecting region 340 located between first sub-array 310A and second sub-array 310B, as shown in FIG. 3C. The plurality of bit line contact structures 313 can further include a plurality of bit line pick-up nodes 315 correspondingly. Bit line contact structures 313 is wider than bit line contact structures 312 along the bit line direction (the y-direction), making it easier to form bit line pick-up nodes 315 on bit line contact structures 313. For example, bit line pick-up nodes 315 can be staggered with each other along the channel direction (the x-direction). The parasite capacitance between two adjacent bit line pick-up nodes 315 is reduced as a distance between them are increased by the staggered arrangement.

In some implementations, bit line pick-up nodes 314 of memory array 310 are aligned on a same line along the word line direction (the x-direction), as shown in FIG. 3A. In some implementations, bit line pick-up nodes 314 in a first row along the word line direction (the x-direction) are staggered with bit line pick-up nodes 314 in a second row along the word line direction (the x-direction), as shown in FIG. 3C.

In the present disclosure, bit line contact structures 312 are integrated into the structure of vertical capacitors 304 of the memory array and can be formed in a same fabrication process as the vertical capacitors 304. Therefore, areas occupied by bit line contact structures 312 are greatly reduced. For example, in some implementations, a first distance D1 occupied by bit line contact structures 312 can be reduced to 360 nm, and a second distance D2 between two adjacent memory arrays 310 can be reduced to 150 nm. The areas occupied by bit line contact structures 312 can occupy less than 1% of the total area of the memory device, which is significantly reduced compared to memory device 200 as described above.

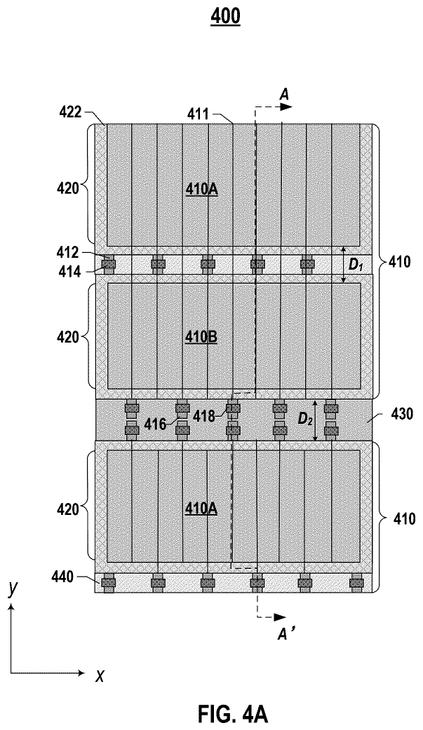

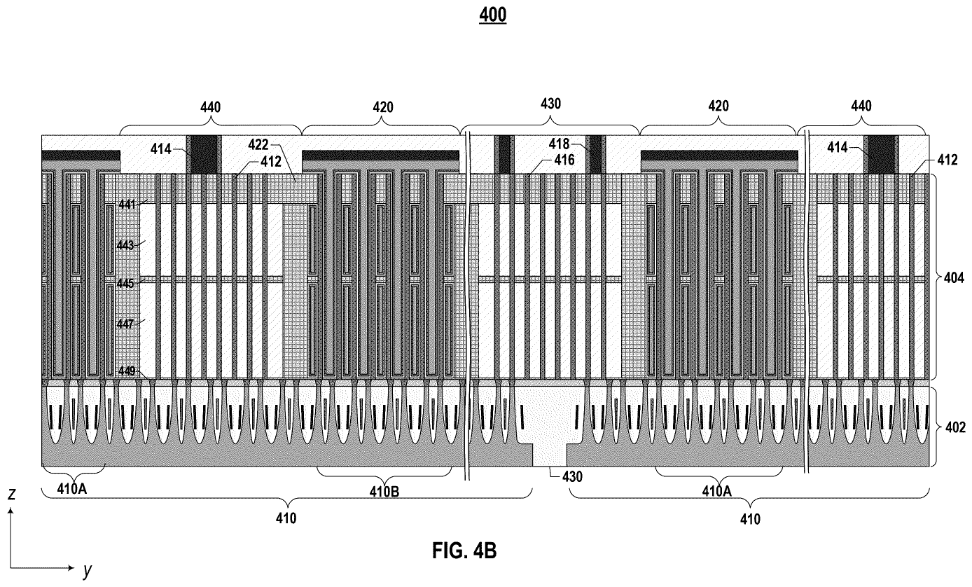

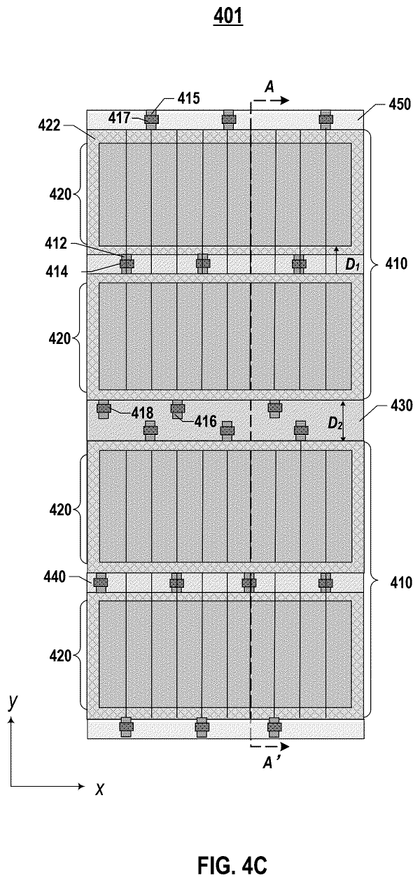

FIG. 4A illustrates a schematic plan view of a memory device 400 including a plurality of memory arrays 410 in the x-y plane, FIG. 4B is a cross-sectional view of memory device 400 in FIG. 4A along AA′ direction, FIG. 4C illustrates a schematic plan view of a memory device 401 including a plurality of memory arrays 410 in the x-y plane, according to some implementations of the present disclosure. Each memory array 410 can include an array of memory cells each including a vertical transistor 402 and a vertical capacitor 404. Vertical transistor 402 can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 4A, each memory array 410 can include a plurality of bit lines 411 each extending in the bit line direction (the y-direction). It is noted that, each memory array 410 can further include a plurality of word lines (not shown) each extending in the word line direction (the x-direction). The word lines and bit lines 411 may be formed in different lateral planes for ease of routing. In some implementations, each memory array 410 can further include a first sub-array 410A and a second sub-array 410B, and memory device 400 can further include a plurality of bit line contact structures 412 coupled with the bit lines 411. It should be noted that one and a half memory arrays 410 are illustrated in FIGS. 4A and 4B. That is, a second sub-array 410B of one of memory arrays 410 is omitted in FIGS. 4A and 4B. It should be noted that the figures in the present disclosure are illustrative, and it is understandable for people having ordinary skills in the art that each memory array 410 is provided with two sub-arrays.

In some implementations, bit line contact structures 412 are formed in a first connecting region 440 located between first sub-array 410A and second sub-array 410B, as shown in FIGS. 4A and 4B. In some implementations, memory device 400 further includes bit line contact structures 416 located in a second connecting region 430 at a first edge of the memory array 410. This second connecting region 430 is positioned away from first connecting region 440, as illustrated in FIGS. 4A and 4B. Each memory array 410 is thus equipped with two connecting regions for the purpose of bit line connectivity, resulting in a reduction of interconnector density within each region. This design facilitates the formation of bit line pick-up nodes 414 and 418. In this implementation, the area occupied by the first connecting region 440 and the second connecting region 430 is increased, while the density of contact structures in each region is correspondingly reduced.

Referring to FIG. 4B, first connecting region 440 and second connecting region 430 align with vertical capacitors 404 in all lateral directions. In some implementations, bit line contact structures 412 and 416 have a same size with vertical capacitors 404 along the channel direction. In some implementations, first connecting region 440 and second connecting region 430 can include a stacked-structure in a channel direction (the z-direction). For instance, as shown in FIG. 4B, the stacked-structure includes a first layer 441, a second layer 443, a third layer 445, a fourth layer 447, and fifth layer 449. In some implementations, all the five layers of the stacked-structure are dielectric layers including, but not limited to, silicon oxide, silicon nitride, silicon oxynitride, low-k dielectrics, or any combination thereof. In some implementations, the materials of any two adjacent dielectric layers are different. For example, first layer 441, third layer 445, and fifth layer 449 are formed by silicon oxide, and second layer 443 and fourth layer 447 are formed by silicon nitride.

In some implementations, along the bit line direction (the y-direction), bit lines 411 coupled to transistors 402 in a first array of memory arrays 410 are truncated from bit lines 411 coupled to transistors 402 in a second array of memory arrays 410 by a second connecting region 430, as shown in FIGS. 4A and 4B. Bit line contact structures 416 in second connecting region 430 is formed on dielectric structure 330 in the channel direction (the z-direction). In some implementations, along the bit line direction (the y-direction), transistors 402 in first sub-array 410A share bit lines with corresponding transistors 402 in second sub-array 410B. That is, transistors 402 in first sub-array 410A and second sub-array 410B share a same set of bit lines 411, and bit line contact structures 412 in first connecting region are located in the middle of bit lines 411, as shown in FIG. 4A.

In some implementations, along the bit line direction (the y-direction), vertical capacitors 404 in first sub-array 410A and vertical capacitors 404 in second sub-array 410B are separated by at least two isolation walls 422, and bit line contact structures 412 are located between the at least two isolation walls 422. For example, as shown in FIG. 4A, a first isolation wall 422 is formed between first sub-array 410A and first connecting region 440 to separate the memory cells in first sub-array 410A from bit line contact structures 412 in first connecting region 440. A second isolation wall 422 is formed between second sub-array 410B and first connecting region 440 to separate the memory cells in second sub-array 410B from bit line contact structures 412 in first connecting region 440. A parasite capacitance of the bit line contact structures 412 are greatly reduced by isolation walls 422. In some implementations, transistors 402 covered by isolation walls 422 and bit line contact structures 412 located between isolation walls 422 are dummy transistors as they are not connected with any vertical capacitors 404. It should be noted that the number of vertical capacitors 404, the number of bit line contact structures 412 and 416, and the number of transistors 402 in the figures of the present disclosure are illustrative and should not be read as limitations of the present disclosure.

In some implementations, isolation walls 422 can include a plurality of enclosed structures 420. For example, as shown in FIGS. 4A-4C, isolation walls 422 include a plurality of first enclosed structure 420 with a rectangle shape. Bit line contact structures 412 are located between two adjacent enclosed structures 420. The vertical capacitors 404 in each sub-array are enclosed by a corresponding enclosed structure 420 and form a capacitor array, as shown in FIGS. 4A and 4B.

In some implementations, the plurality of bit line contact structures 412 can further include a plurality of bit line pick-up nodes 414 correspondingly, and the plurality of bit line contact structures 416 can further include a plurality of bit line pick-up nodes 418 correspondingly. Referring to FIG. 4B, bit line pick-up nodes 414 and 418 are formed on bit line contact structures 412 and 416 and are configured to connect bit lines 311 with contacts of an interconnect layer. Each bit line pick-up node 414 contacts with at least one bit line contact structures 412, each bit line pick-up node 418 contacts with at least one bit line contact structures 416. In some implementations, bit line pick-up node 418 can pick up bit lines 411 by connecting any one of bit line contact structures 416 because each bit line 411 is connected to a plurality of bit line contact structures 416, as shown in FIG. 4B. In some implementations, each bit line can be picked up by either bit line pick-up node 414 or bit line pick-up node 418. In some implementations, bit line pick-up node 414 staggered with bit line pick-up node 418, as shown in FIG. 4A.

In the present implementations, bit line pick-up nodes 414 and 418 are integrated into the structure of vertical capacitors 404 of the memory array and can be formed in a same fabrication process as the vertical capacitors 404. Therefore, areas occupied by bit line contact structures 412 and 416 are greatly reduced. For example, in some implementations, a first distance D1 occupied by bit line contact structures 412 can be reduced to 360 nm, and a second distance D2 occupied by bit line contact structures 416 can be reduced to 510 nm. The areas occupied by bit line contact structures 412 and 416 can occupy less than 2% of the total area of the memory device, which are significantly reduced compared to memory device 200 as described above. The interconnector density of memory device 400 is also reduced compared to memory device 200.

In some implementations, as shown in FIG. 4C, a memory device 401 is provided. Memory device 401 further includes bit line contact structures 416 located in a second connecting region 430 at a first edge of the memory array 410 and bit line contact structures 417 located in a third connecting region 415 at a second edge of the memory array 410. Both the first edge and the second edge are away from first connecting region 440, as illustrated in FIG. 4C. Second connecting region 430 and third connecting region 450 are located at two opposite sides of memory array 410. Each memory array 410 is thus equipped with three connecting regions for the purpose of bit line connectivity, interconnector density within each region is further reduced compared to memory device 400, as shown in FIGS. 4A and 4C.

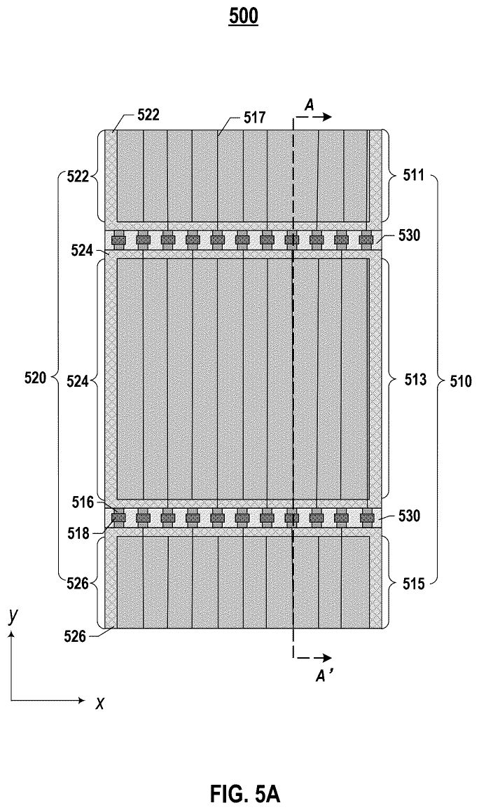

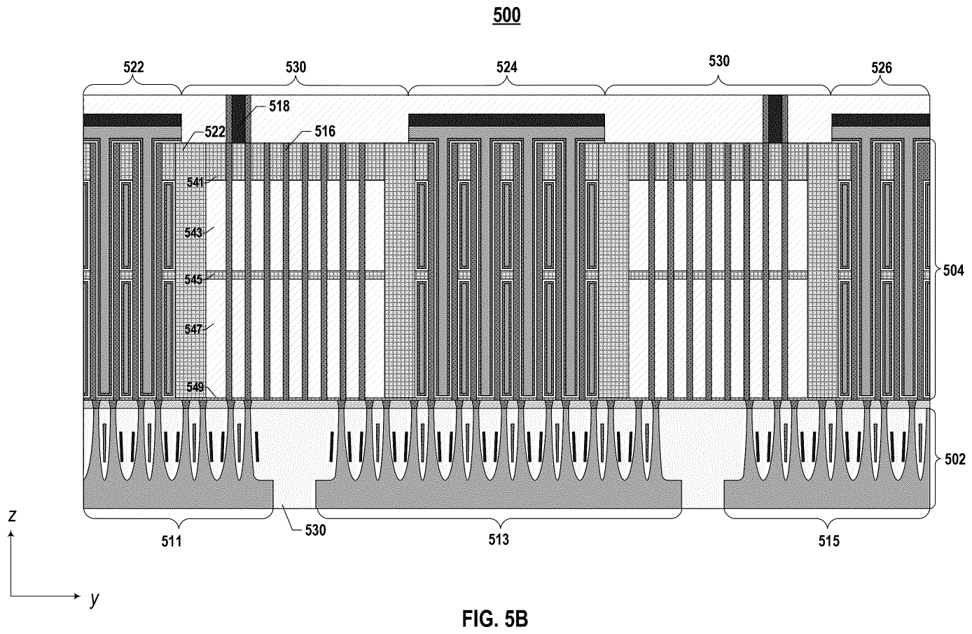

FIG. 5A illustrates a schematic plan view of a memory device 500 including a plurality of memory arrays 510 in the x-y plane, FIG. 5B is a cross-sectional view of memory device 500 in FIG. 5A along AA′ direction, according to some implementations of the present disclosure. Each memory array 510 can include an array of memory cells each including a vertical transistor 502 and a vertical capacitor 504. Vertical transistor 502 can have any suitable arrangement of the components, according to some implementations of the present disclosure, such as a channel-all-around (CAA) type vertical transistor, a gate-all-around type vertical transistor, a single-metal-gate (SMG) type vertical transistor, a double-metal-gate (DMG) type vertical transistor, a triple-metal-gate (TMG) type vertical transistor, etc.

As shown in FIG. 5A, each memory array 510 can include a plurality of bit lines 517 each extending in the bit line direction (the y-direction). It is noted that, each memory array 510 can further include a plurality of word lines (not shown) each extending in the word line direction (the x-direction). The word lines and bit lines 517 may be formed in different lateral planes for ease of routing. In some implementations, memory device 500 can further include a plurality of bit line contact structures 516 coupled with the bit lines 517. The plurality of bit line contact structures 516 can further include a plurality of bit line pick-up nodes 518 correspondingly. The bit line contact structures 516 are formed in a second connecting region 530 located in at least one edge of memory array 510, as shown in FIGS. 5A and 5B.

Referring to FIG. 5B, second connecting region 530 aligns with vertical capacitors 504 in all lateral directions. In some implementations, bit line contact structures 516 have a same size as vertical capacitors 504 along the channel direction. In some implementations, second connecting region 530 can include a stacked-structure in a channel direction (the z-direction). For instance, as shown in FIG. 5B, the stacked-structure includes a first layer 541, a second layer 543, a third layer 545, a fourth layer 547, and fifth layer 549. In some implementations, all the five layers of the stacked-structure are dielectric layers including, but not limited to, silicon oxide, silicon nitride, silicon oxynitride, low-k dielectrics, or any combination thereof. In some implementations, the materials of any two adjacent dielectric layers are different. For example, first layer 541, third layer 545, and fifth layer 549 are formed by silicon oxide, and second layer 543 and fourth layer 547 are formed by silicon nitride.

In some implementations, along the bit line direction (the y-direction), bit lines 517 coupled to transistors 502 in a first array of memory arrays 510 are truncated from bit lines 517 coupled to transistors 502 in a second array of memory arrays 510, as shown in FIGS. 5A and 5B.

In some implementations, along the bit line direction (the y-direction), memory device 500 includes a first memory array 511, a second memory array 513, and a third memory array 515. First memory array 511 and second memory array 513 are separated by at least a first isolation wall 522 and a second isolation wall 524, and bit line contact structures 516 are located between first isolation wall 522 and second isolation wall 524. Second memory array 513 and third memory array 515 are separated by at least second isolation wall 524 and a third isolation wall 526, and bit line contact structures 516 are located between second isolation wall 524 and third isolation wall 526. For example, as shown in FIG. 5A, first isolation wall 522 is formed between first memory array 511 and second connecting region 530 to separate the memory cells in a first memory array 511 from bit line contact structures 516 in second connecting region 530. A second isolation wall 524 is formed between a second memory array 513 and second connecting region 530 to separate the memory cells in second memory array 513 from bit line contact structures 516 in second connecting region 530. In some implementations, a third isolation wall 526 is formed between the third memory array 515 and second connecting region 530 to separate the memory cells in third memory array 515 from bit line contact structures 516 in second connecting region 530. A parasite capacitance of the bit line contact structures 516 are greatly reduced by the isolation walls.

In some implementations, isolation walls 522 can include a plurality of enclosed structures 520. For example, as shown in FIGS. 5A and 5B, first isolation wall 522, second isolation wall 524, and third isolation wall 526 are all enclosed structure with a rectangle shape. Bit line contact structures 516 are located between two adjacent enclosed structures. For example, bit line contact structures 516 locates between first isolation wall 522 and second isolation wall 524, as well as between second isolation wall 524 and third isolation wall 526. Vertical capacitors 504 enclosed by first enclosed structure 520 forms a first capacitor array including vertical capacitors 504 in first memory array 511. Vertical capacitors 504 enclosed by second enclosed structure 524 forms a second capacitor array including vertical capacitors 504 in second memory array 513. Vertical capacitors 504 enclosed by third enclosed structure 526 forms a capacitor array including vertical capacitors 504 in third memory array 515. As shown in FIGS. 5A and 5B, the capacitor arrays have a same scope as the corresponding memory arrays.

In some implementations, the plurality of bit line contact structures 516 can further include a plurality of bit line pick-up nodes 518 correspondingly. Referring to FIG. 5B, bit line pick-up nodes 518 are formed on bit line contact structures 516 and are configured to connect bit lines 517 with contacts of an interconnect layer. Each bit line pick-up node 518 contacts with at least one bit line contact structures 516. In some implementations, bit line pick-up node 518 can pick up bit lines 517 by connecting any one of bit line contact structures 516 because each bit line 517 is connected to a plurality of bit line contact structures 516, as shown in FIG. 5B. In some implementations, bit line pick-up nodes 518 of memory array 510 are aligned on a same line along the word line direction (the x-direction), as shown in FIG. 5A. In some implementations, bit line pick-up nodes 518 in a first row along the word line direction (the x-direction) are staggered with bit line pick-up nodes 518 in a second row along the word line direction (the x-direction), as shown in FIG. 5B.

In the present disclosure, bit line contact structures 516 are integrated into the structure of vertical capacitors 504 of the memory array and can be formed in a same fabrication process as the vertical capacitors 504. Therefore, areas occupied by bit line contact structures 516 are greatly reduced. For example, in some implementations, a distance occupied by bit line contact structures 516 can be reduced to 360 nm. The areas occupied by bit line contact structures 516 can occupy less than 0.5% of the total area of the memory device, making it easy to downsize the memory array 510 to decrease capacitance.

The bit line contact structures described in the implementations above can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, the bit line contact structures can include multiple conductive layers, such as a W layer over a TiN layer.

As shown in FIG. 3B, FIG. 4B, and FIG. 5B, each memory device includes a transistor layer having a plurality of transistors. Each vertical transistor has a semiconductor layer and a gate electrode at one or more lateral sides of semiconductor layer. In some implementations, the bit lines are in contact with the lower ends of the semiconductor layer. In some implementations, the bit line contact structures can extend through the bit line and into the semiconductor layer of the transistor layer. The gate electrode can be located at one or more lateral sides of the semiconductor layer to form CAA type, SMG type, DMG type, or TMG type vertical transistor. In some implementations, the gate electrodes of a row of the transistors along the bit line direction (the x-direction) can be connected with each other to form the word line.

The gate electrode can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the gate electrode may include doped polysilicon, i.e., gate poly. In some implementations, the gate electrode includes multiple conductive layers, such as a W layer over a TiN layer. In some implementations, a gate dielectric layer can be located between the semiconductor layer and the gate electrode. The gate dielectric layer can include any suitable dielectric materials, such as silicon oxide, silicon nitride, silicon oxynitride, or high-k dielectrics.

Bit line contact structures can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. In some implementations, the bit line contact structures can include multiple conductive layers, such as a W layer over a TiN layer.

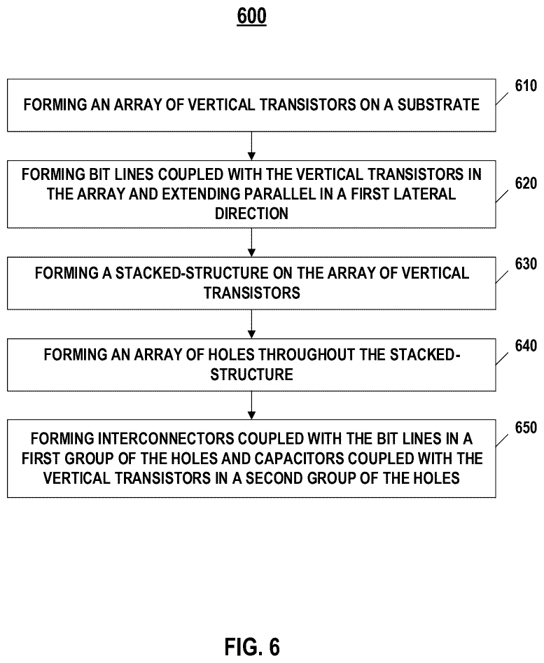

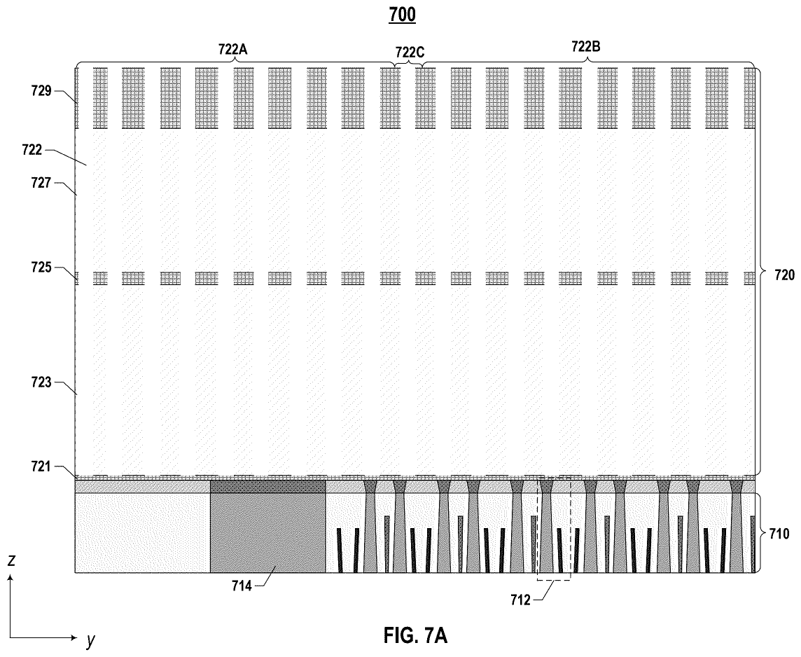

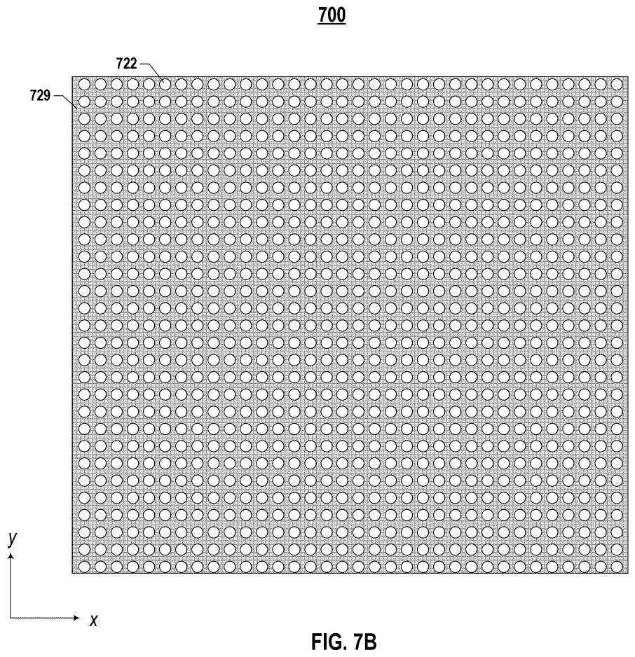

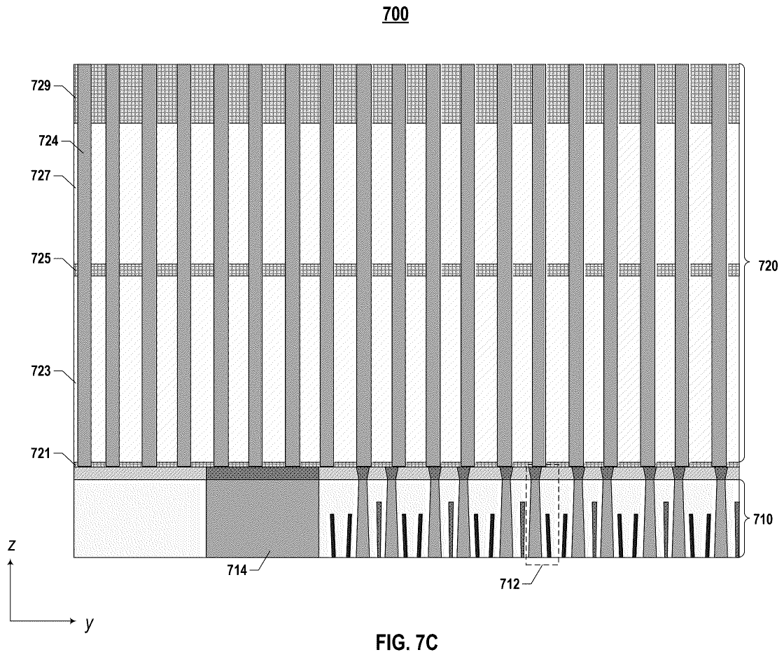

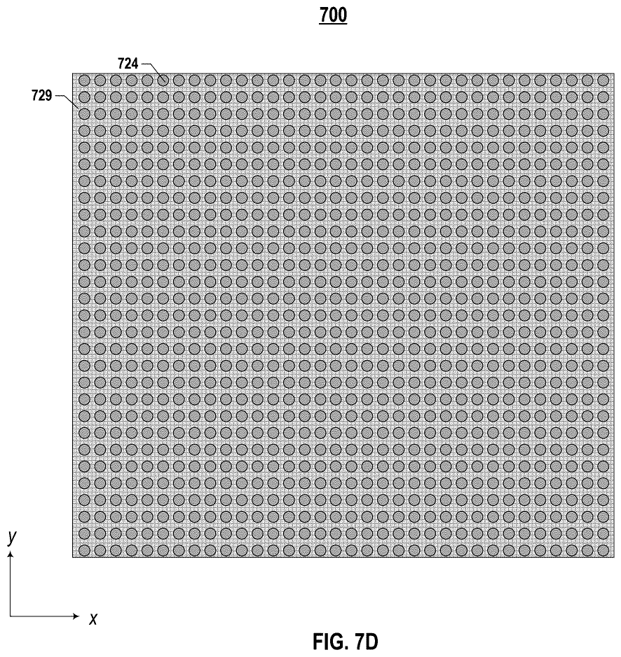

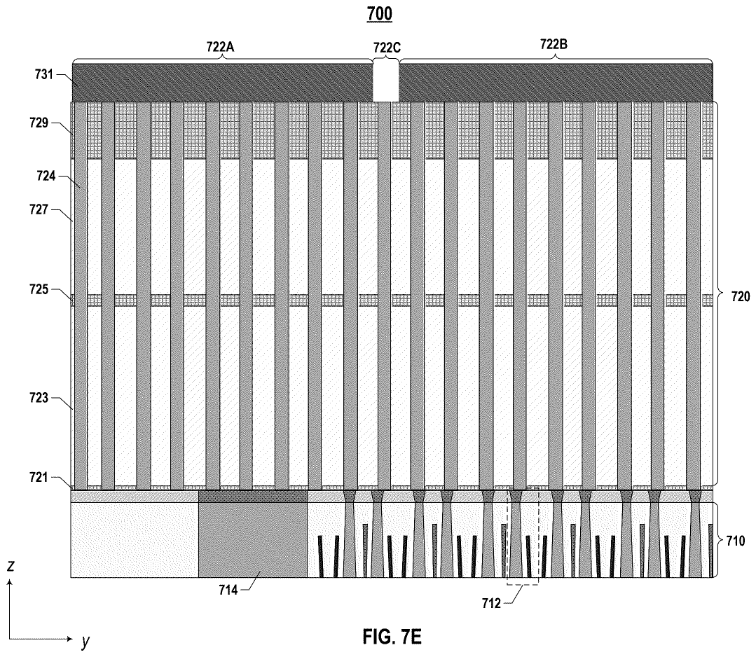

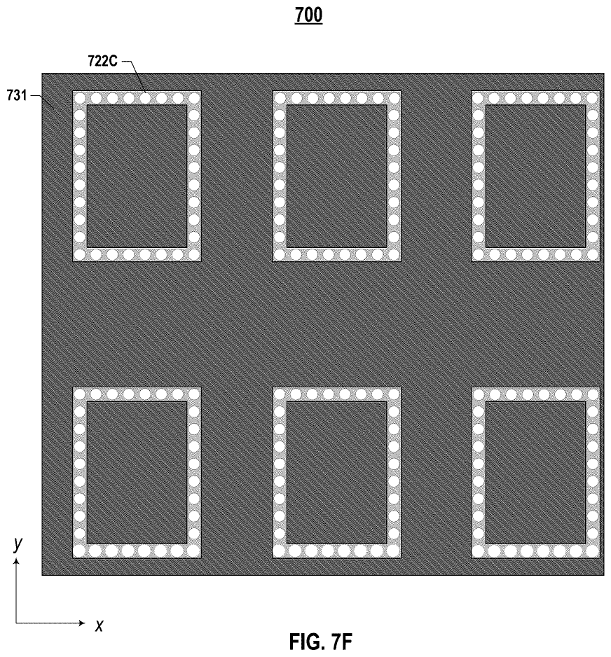

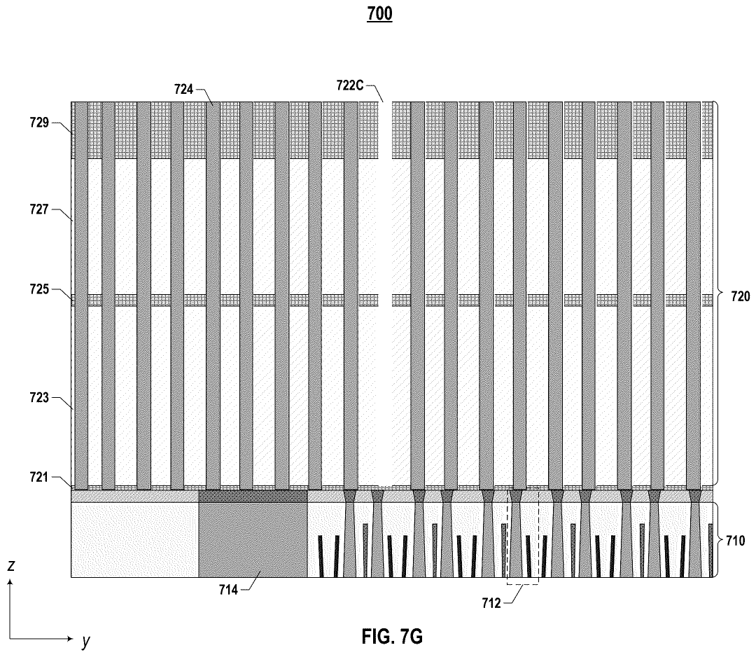

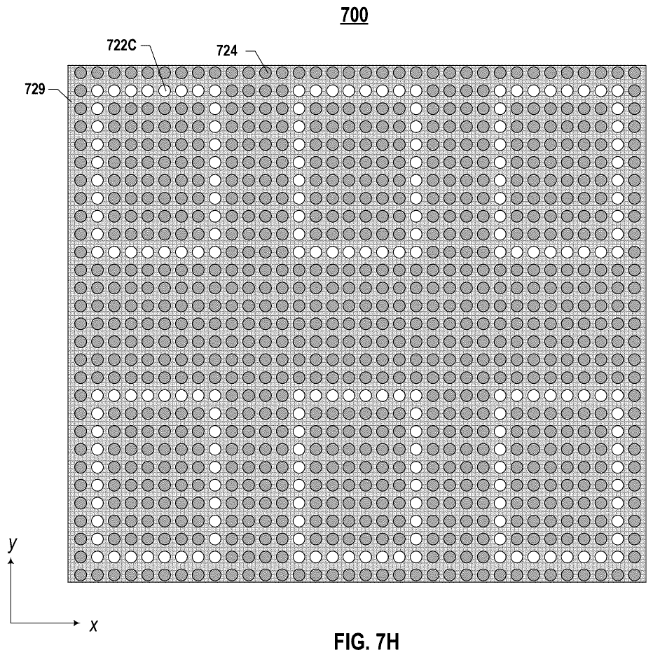

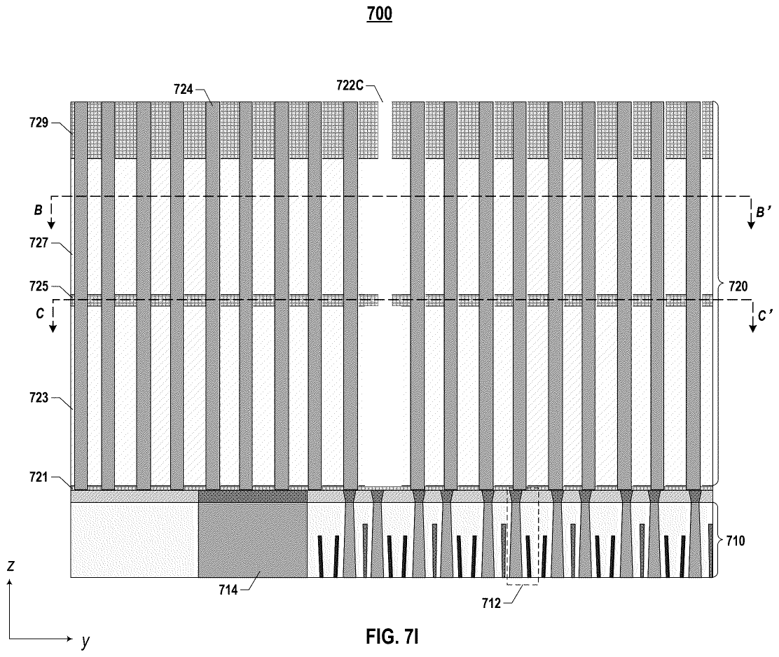

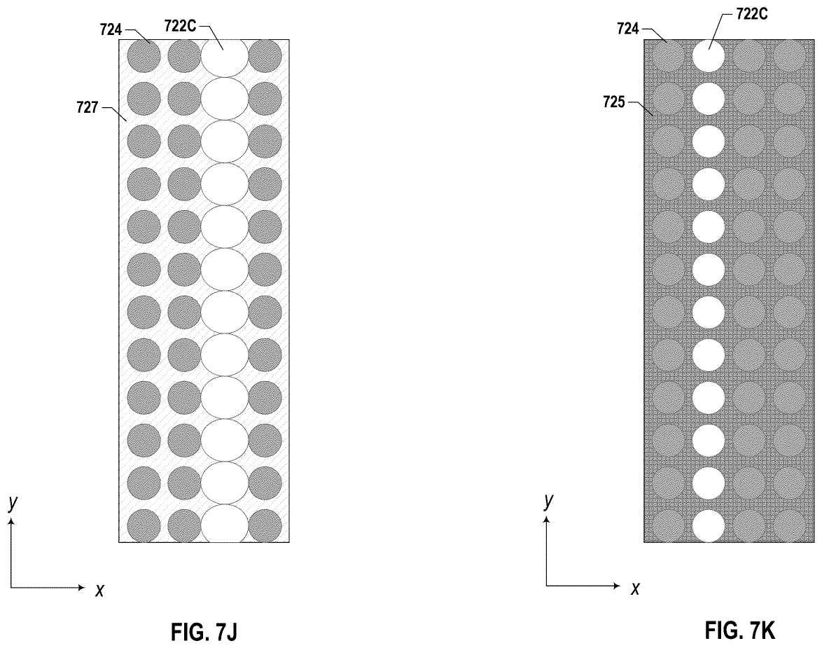

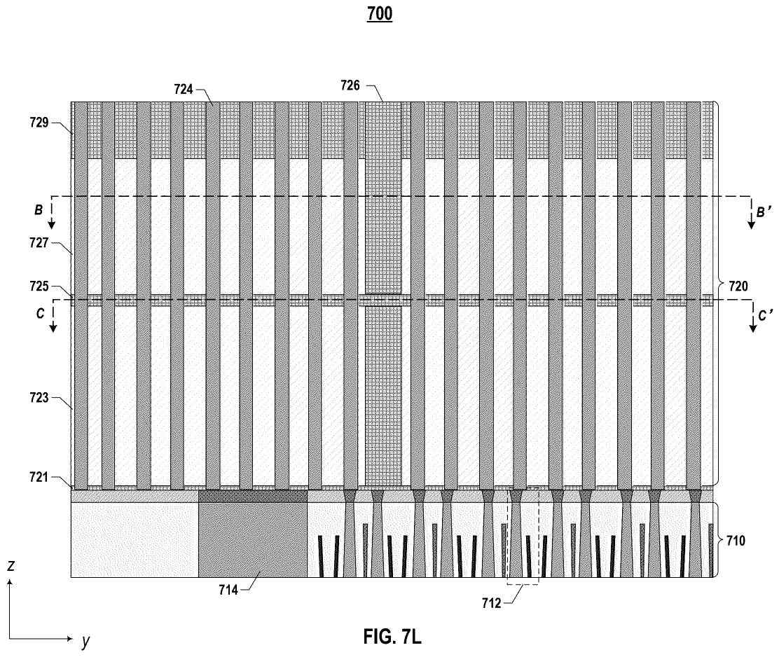

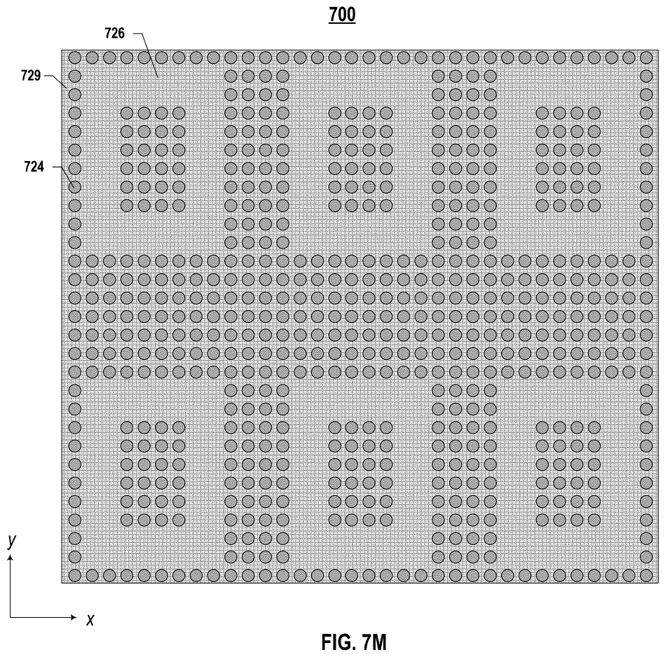

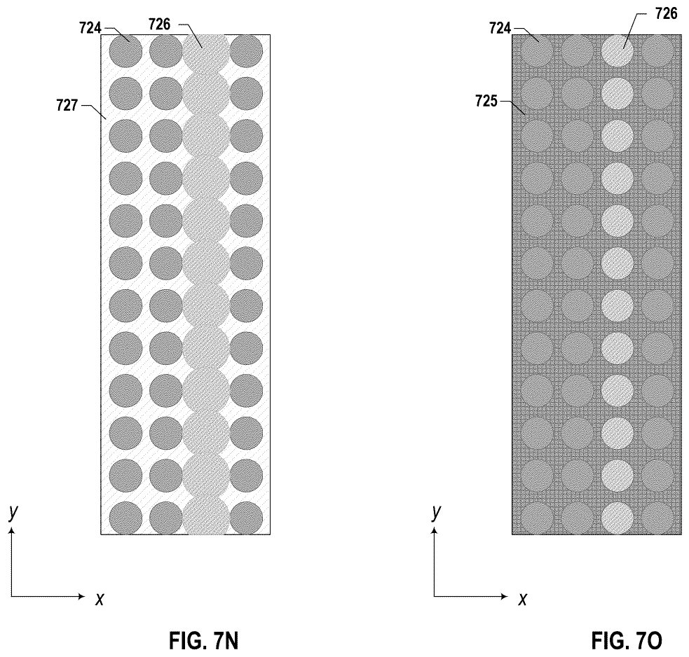

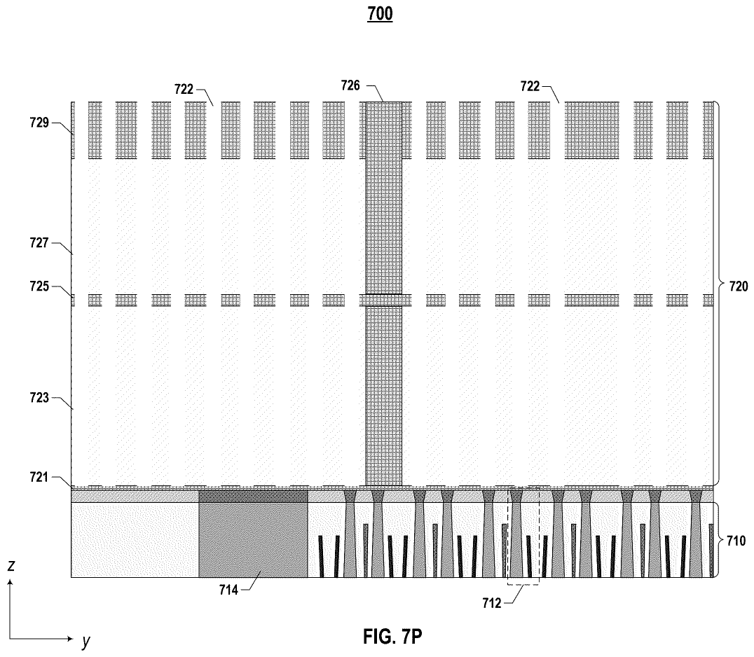

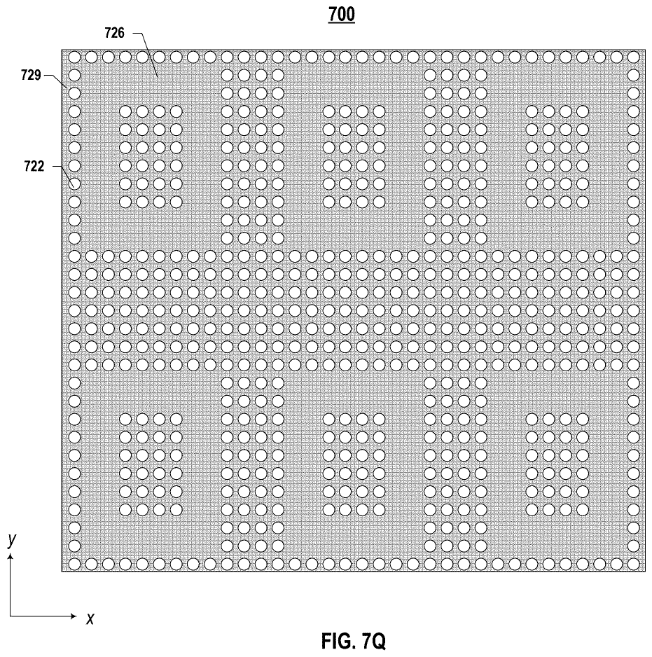

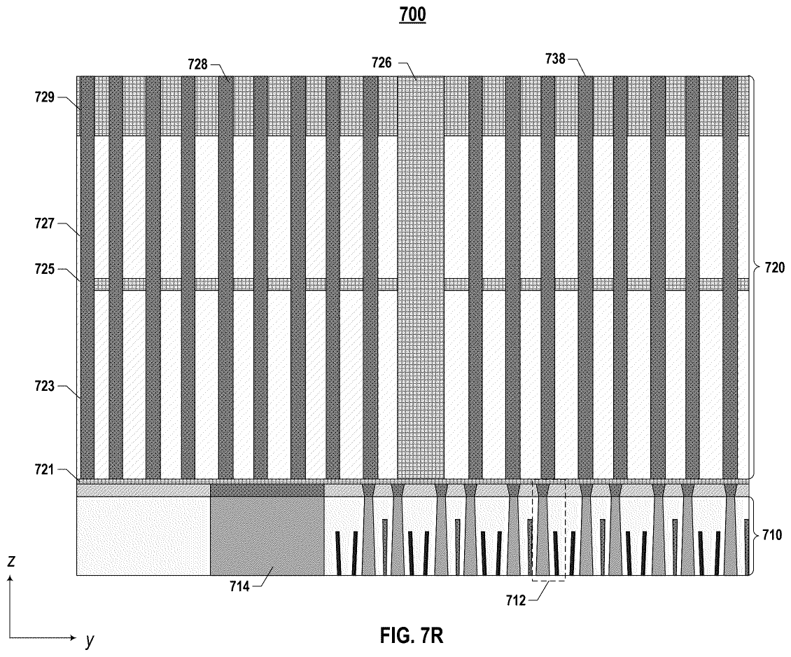

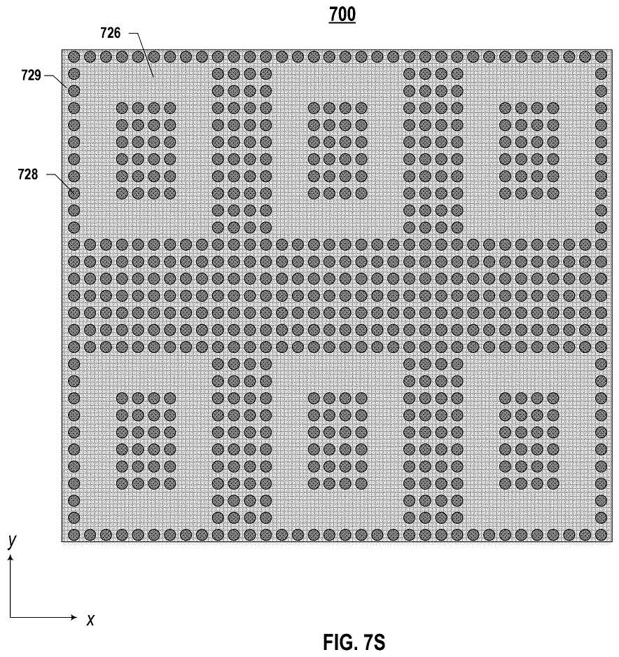

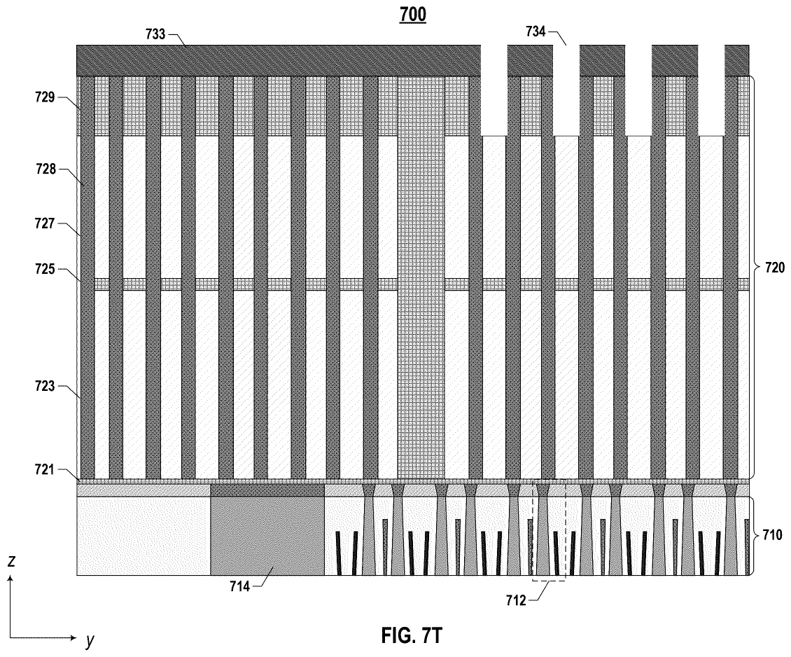

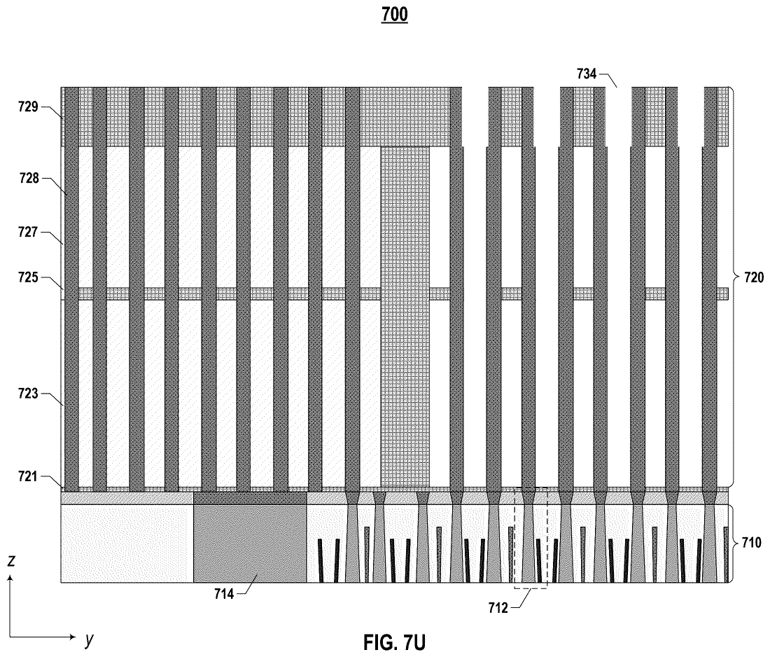

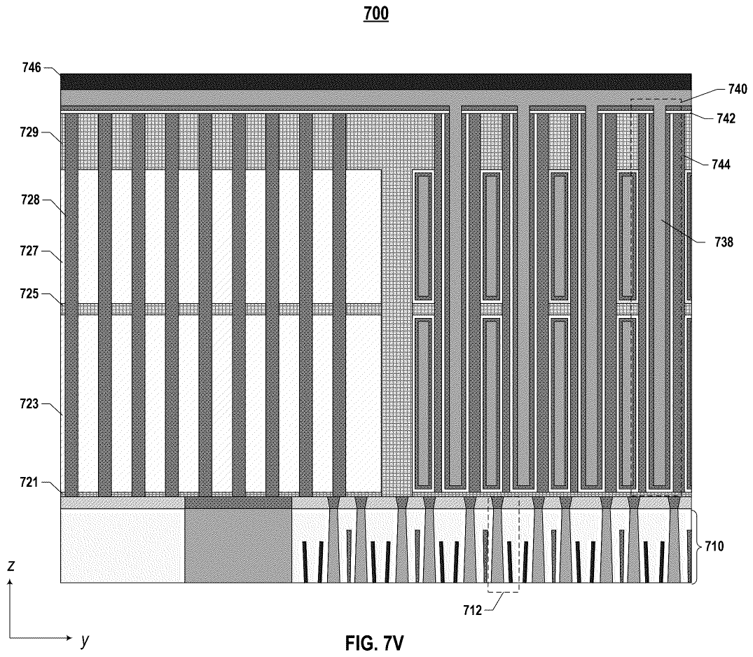

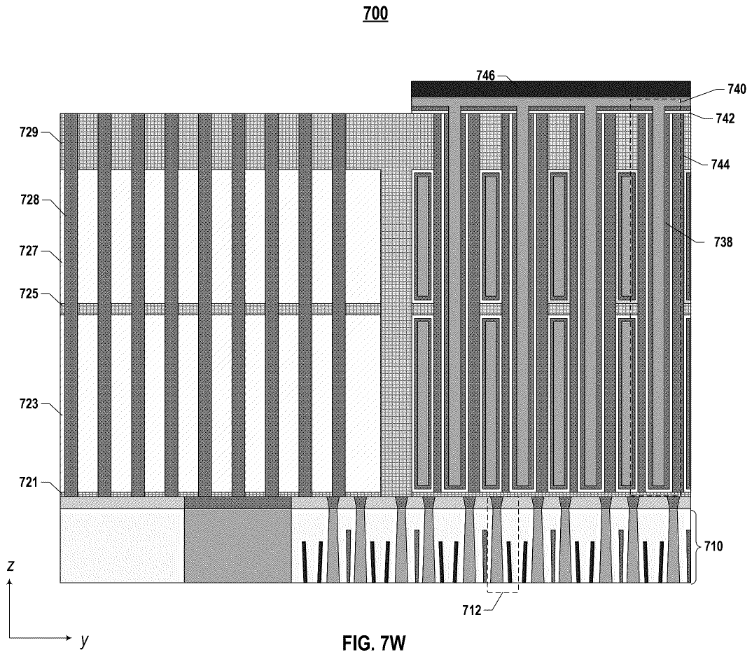

FIG. 6 illustrates a flowchart of a fabricating method 600 for forming a 3D memory device, according to some implementations of the present disclosure. FIGS. 7A-7W illustrate schematic side cross-sectional views of a 3D memory device at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 610, in which an array of transistors can be formed on a substrate. Method 600 can then proceed to operation 620, in which bit lines are formed to couple with the transistors in the array and extending in a bit line direction (the y-direction). FIG. 7A illustrates a schematic side cross-sectional view of the 3D memory device 700 in the x-z plane at a certain stage of operation 610 of method 600. FIG. 7B illustrates a schematic top view of 3D memory device 700 in FIG. 7A.

As shown in FIG. 7A, a vertical transistor layer 710 including a plurality of transistors 712 is formed on a substrate (not shown). A plurality of bit lines 714 can be formed coupling with the plurality of transistors 712. In some implementations, the substrate can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. Each vertical transistor 712 having a semiconductor layer and a gate electrode at one or more lateral sides of semiconductor layer. In some implementations, the bit lines are in contact with the lower ends or upper ends of the semiconductor layer and are picked out of the vertical transistor layer 710 as shown in FIG. 7A. The gate electrode can be located at one or more lateral sides of the semiconductor layer to form CAA type, SMG type, DMG type, or TMG type vertical transistor. In some implementations, the gate electrodes of a row of the transistors along the bit line direction (the x-direction) can be connected with each other to form the word line. The gate electrode can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the gate electrode may include doped polysilicon, i.e., gate poly. In some implementations, the gate electrode includes multiple conductive layers, such as a W layer over a TiN layer. In some implementations, a gate dielectric layer can be located between the semiconductor layer and the gate electrode. The gate dielectric layer can include any suitable dielectric materials, such as silicon oxide, silicon nitride, silicon oxynitride, or high-k dielectrics.

Referring back to FIG. 6, method 600 can proceed to operation 630, in which a stacked-structure 720 can be formed on the array of transistors. As shown in FIG. 7A, in some implementations, stacked-structure 720 includes a first layer 721, a second layer 723, a third layer 725, a fourth layer 727, and a fifth layer 729. In some implementations, all the five layers of stacked-structure 720 are dielectric layers including, but not limited to, silicon oxide, silicon nitride, silicon oxynitride, low-k dielectrics, or any combination thereof. In some implementations, the materials of any two adjacent dielectric layers are different. For example, first layer 721, third layer 725, and fifth layer 729 are formed by silicon oxide, and second layer 723 and fourth layer 727 are formed by silicon nitride. In some implementations, the five layers of stacked-structure 720 can be formed by thermal oxidation, oxide growth, chemical vapor deposition (CVD), atomic layer deposition (ALD), physical vapor deposition (PVD), or sputtering.

Referring to FIG. 6, method 600 can proceed to operation 640, in which an array of holes 722 is formed throughout stacked-structure 720, as shown in FIGS. 7A and 7B. The array of holes 722 includes a first group of the holes 722A configured to form contact structures coupled with the bit lines 714, a second group of the holes 722B configured to form capacitors coupled with the transistors 712, and a third group of the holes 722C configured to form isolation walls.

In some implementations, deep reactive ion etching (DRIE) is used to etch deep holes into stacked-structure 720 as a depth of holes 722 is relatively large, and DRIE can produce high aspect ratio features (depth to width ratio). DRIE typically operates in a cyclic manner, alternating between an etching step (using a gas like SF₆) and a passivation step (using a gas like C₄F₈) to create a well-defined, vertical profile. A top view of the array of holes 722 is shown in FIG. 7B.

Referring to FIG. 6, method 600 can proceed to operation 650, in which contact structures coupled with the bit lines are formed in a first group of the holes, and capacitors coupled with the transistors are formed in a second group of the holes.

In some implementations, referring to FIGS. 7C and 7D, the array of holes 722 is filed with a sacrifice material 724, different from the material of stacked-structure 720. FIG. 7C illustrates a schematic side cross-sectional view of the 3D memory device 700 in the x-z plane after sacrifice material 724 is formed in the array of holes 722. FIG. 7D illustrates a schematic top view of 3D memory device 700 in FIG. 7C.

That is, sacrifice material 724 is different from the material of all the first layer 721, second layer 723, third layer 725, fourth layer 727, and fifth layer 729. In some implementations, sacrifice material 724 may be silicon oxynitride or other low-k dielectrics.

In some implementations, referring to FIGS. 7E and 7F, a first mask 731 is formed on stacked-structure 720 to cover the first group of holes 722A and the second group of holes 722B. FIG. 7E illustrates a schematic side cross-sectional view of the 3D memory device 700 in the x-z plane after first mask 731 is formed. FIG. 7E illustrates a schematic top view of 3D memory device 700 in FIG. 7E. In some implementations, first mask 731 can be a layer of photoresist applied on stacked-structure 720, then photolithography is used to expose the photoresist to UV light through a hard mask that defines regions for first group of holes 722A, second group of holes 722B, and third group of holes 722C. As shown in FIG. 7F, third group of holes 722C forms a rectangle shape, first group of holes 722A includes holes 722 surrounded by the rectangle shape, and second group of holes 722B includes holes 722 outside the rectangle shape. Then the photoresist is developed to create openings where sacrifice material 724 in third group of holes 722C will be removed. A dry/wet etching process can be performed to remove sacrifice material 724.

In some implementations, referring to FIGS. 7G and 7H, first mask 731 is removed after sacrifice material 724 in third group of holes 722C being etched. FIG. 7G illustrates a schematic side cross-sectional view of the 3D memory device 700 in the x-z plane after first mask 731 is removed. FIG. 7H illustrates a schematic top view of 3D memory device 700 in FIG. 7G. In some implementations, referring to FIGS. 7I-7K, third group of holes 722C are expanded to increase a thickness of an isolation wall. FIG. 7I illustrates a schematic side cross-sectional view of the 3D memory device 700 in the x-z plane after third group of holes 722C being expanded. FIG. 7J illustrates a partial cross-sectional view of memory device 700 along the BB′ direction in FIG. 7I. FIG. 7K illustrates a partial cross-sectional view of memory device 700 along the CC′ direction in FIG. 7I. As the material of first layer 721, third layer 725, and fifth layer 729 are different from the material of second layer 723 and fourth layer 727, second layer 723 and fourth layer 727 can be removed selectively. In some implementations, first layer 721, third layer 725, and fifth layer 729 are formed by silicon oxide, and second layer 723 and fourth layer 727 are formed by silicon nitride. A wet etching with Buffered Oxide Etch (BOE) can be employed to remove silicon nitride and will not significantly affect silicon nitride. For example, a mixture of hydrofluoric acid (HF) and ammonium fluoride (NH₄F) can be used to remove silicon nitride. In some implementations, a plasma etching process can be used to selectively remove silicon nitride.

FIG. 7J is a partial cross-sectional view along BB′ direction in FIG. 7I, in which at least part of fourth layer 727 surrounding the third group of holes 722C is removed. FIG. 7K is a partial cross-sectional view along CC′ direction in FIG. 7I, in which third layer 725 surrounding the third group of holes 722C has remained. As shown in FIGS. 7I and 7J, a size of the third group of holes 722C located at fourth layer 727 is greatly expanded than the size of the third group of holes 722C located at third layer 725, and the holes 722C in the third group are punched through in the word line direction to form at least one isolation trench. The isolation trench can be an enclosed structure, such as a rectangle-shaped structure.

In some implementations, referring to FIGS. 7L-7O, forming isolation walls 726 in the at least one isolation trench by depositing a dielectric material in the isolation trench. FIG. 7L illustrates a schematic side cross-sectional view of the 3D memory device 700 in the x-z plane after isolation walls 726 are formed. FIG. 7M illustrates a schematic top view of 3D memory device 700 in FIG. 7L. FIG. 7N illustrates a partial cross-sectional view of memory device 700 along the BB′ direction in FIG. 7L. FIG. 7O illustrates a partial cross-sectional view of memory device 700 along the CC′ direction in FIG. 7L. The dielectric material of isolation walls 726 is different from the material of the second dielectric layer. In some implementations, the material of isolation walls 726 is the same as the material of first layer 721, third layer 725, and fifth layer 729, such as silicon oxide in some implementations.

In some implementations, referring to FIGS. 7P-7Q, removing sacrifice material in the first group of holes 722A and second group of holes 722B. FIG. 7P illustrates a schematic side cross-sectional view of the 3D memory device 700 in the x-z plane after the sacrifice material is removed. FIG. 7Q illustrates a schematic top view of 3D memory device 700 in FIG. 7P. As the sacrifice material is different from first layer 721, second layer 723, third layer 725, fourth layer 727, and fifth layer 729, the sacrifice material can be removed by selective etching, such as BOE or plasma etching process.

In some implementations, referring to FIGS. 7R-7S, filing the first group of holes 722A and second group of holes 722B with conductive material. FIG. 7R illustrates a schematic side cross-sectional view of the 3D memory device 700 in the x-z plane after conductive material is formed. FIG. 7S illustrates a schematic top view of 3D memory device 700 in FIG. 7R. The conductive material formed in first group of holes 722A is located outside isolation walls 726 and coupled with bit line 714, that is, bit line contact structures 728 are formed by the conductive material filed in first group of holes 722A. The conductive material formed in second group of holes 722B is located within isolation walls 726 and coupled with transistors 712. That is, inner electrodes 738 of the vertical capacitors of memory device 700 are formed by conductive material filed in second group of holes 722B. In some implementations, the conductive material can include any suitable conductive materials, such as polysilicon, metals (e.g., W, Cu, Al, etc.), metal compounds (e.g., TiN, TaN, etc.), or silicides. In some implementations, the conductive material can include multiple conductive layers, such as a W layer over a TiN layer. In some implementations, bit line contact structures 728 are integrated into the structure of vertical capacitors of the memory array and can be formed in a same fabrication process as the vertical capacitors. Therefore, areas occupied by bit line contact structures 728 are greatly reduced, making it easy to downsize the memory arrays to decrease capacitance.

In some implementations, referring to FIG. 7T, a second mask 733 is formed on stacked-structure 720 to cover the first group of holes 722A, the second group of holes 722B, and the fifth layer 729 surrounding the first group of holes 722A. As shown in FIG. 7T, at least part of the fifth layer 729 surrounding the second group of holes 722B are exposed from openings 734 of second mask 733. In some implementations, second mask 733 can be a layer of photoresist applied on stacked-structure 720; then photolithography is used to expose the photoresist to UV light through a hard mask that defines regions for the fifth layer 729 surrounding the second group of holes 722B. Then, the photoresist is developed to create openings 734, where the fifth layer 729 surrounding the second group of holes 722B will be removed. A dry/wet etching process can be performed to remove fifth layer 729 under openings 734.

In some implementations, referring to FIGS. 7U and 7V, second layer 723 and fourth layer 727 surrounding the second group of holes 722C are removed to create a space for dielectric layers 742 and outer electrodes 744 of the vertical capacitors 740. As the material of first layer 721, third layer 725, and fifth layer 729 are different from the material of second layer 723 and fourth layer 727, second layer 723 and fourth layer 727 can be removed selectively. In some implementations, first layer 721, third layer 725, and fifth layer 729 are formed by silicon oxide, and second layer 723 and fourth layer 727 are formed by silicon nitride. A wet etching with Buffered Oxide Etch (BOE) can be employed to remove silicon nitride and will not significantly affect silicon nitride. For example, a mixture of hydrofluoric acid (HF) and ammonium fluoride (NH₄F) can be used to remove silicon nitride. In some implementations, a plasma etching process can be used to selectively remove silicon nitride.

In some implementations, first layer 721, third layer 725, and fifth layer 729 can be used as mesh layer for the vertical capacitors during fabrication, as shown in FIG. 7U. Without mesh layer, the vertical capacitors may lean over and contact adjacent vertical capacitors as the size of the vertical capacitors along the channel direction is relatively high. In some implementations, a mesh layer includes first layer 721, third layer 725, and fifth layer 729, and openings 734 are formed on first layer 721, third layer 725, and fifth layer 729 among inner electrodes 738 of the transistors, and each inner electrodes 738 is connected to at least one opening 734 at each layer of first layer 721, third layer 725, and fifth layer 729. In some implementations, every four or six inner electrodes 738 has a same opening 734. In some implementations, opening 734 can be, but not limited to, irregular polygon, round, oval, triangle, rectangular, hexagonal, or other shapes. The number of inner electrodes 738 sharing a same opening 734 can be set as needed, for example, four, six, eight, etc.

In some implementations, referring to FIG. 7V, a plurality of vertical capacitors 740 are formed by forming dielectric layers 742 and outer electrodes 744 surrounding inner electrodes 738. In some implementations, inner electrodes 738 and/or the outer electrodes 744 can include conductive materials including, but not limited to, W, Co, Cu, Al, TiN, TaN, polysilicon, silicide, or any combination thereof. In some implementations, dielectric layers 742 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, outer electrodes 744 include a stacked-structure having multiple conductive layers. For example, outer electrodes 744 can have a first layer of Cu, a second layer of TiN, and a third layer of polysilicon. A contacting resistance of outer electrodes 744 can be greatly reduced by the stacked-structure with multiple conductive layers. In some implementations, outer electrodes 744 are coupled to a common plate 746, as shown in FIG. 7V. In some implementations, referring to FIG. 7W, common plate 746 is patterned to expose bit line contact structures 728.

In some implementations, method 600 further includes any other suitable operations after common plate 746 is patterned. For example, operations can be performed to form bit line pick-up node on bit line contact structures 728. It should be noted that the structure and location of the isolation walls described above are illustrative and should not be read as limitations of the present disclosure. Method 600 can be used to fabricate any memory device employing isolation walls, such as, but not limited to memory device 300, memory device 301, memory device 400, memory device 401, and memory device 500.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations, but should be defined only in accordance with the following claims and their equivalents.

What is claimed is:

1. A memory device, comprising
an array of memory cells in an array region, wherein the array comprises a first sub-array and a second sub-array;
bit lines coupled with the memory cells in the array and extending in a bit line direction;
contact structures in a first connecting region located between the first sub-array and the second sub-array; and
isolation walls located between the contact structures and the first sub-array, or between the contact structures and the second sub-array.

2. The memory device of claim 1, wherein
the first connecting region comprises a stacked-structure stacked along a channel direction, the channel direction is perpendicular to the bit line direction; and
the stacked-structure comprises:
a first dielectric layer;
a second dielectric layer covering the first dielectric layer; and
a third dielectric layer covering the second dielectric layer; wherein
a material of the second dielectric layer is different from a material of the first dielectric layer and the third dielectric layer.

3. The memory device of claim 2, wherein
the contact structures are aligned on a same line along a word line direction, the word line direction is perpendicular to the bit line direction and the channel direction.

4. The memory device of claim 2, wherein
the contact structures in a first row along a word line direction are staggered with the contact structures in a second row along the word line direction, the word line direction is perpendicular to the bit line direction and the channel direction.

5. The memory device of claim 1, further comprising:
contact structures in a second connecting region located at a first edge of the array of memory cells; wherein
the second connecting region is away from the first connecting region.

6. The memory device of claim 5, further comprising:
contact structures in a third connecting region located at a second edge of a first array of memory cells opposite to the first edge; wherein
the first connecting region is located between the second connecting region and the third connecting region.

7. The memory device of claim 2, wherein
the array of memory cells comprises a plurality of transistors and a plurality of capacitors coupled with the transistors; and
the contact structures and the capacitors of the memory cells are located in the stacked-structure.

8. The memory device of claim 7, wherein
a size of the contact structures surrounded by the stacked-structure along the channel direction equals to a size of the capacitors surrounded by the stacked-structure along the channel direction.

9. The memory device of claim 7, wherein
along the bit line direction, bit lines coupled to transistors in a first array of memory cells are truncated from bit lines coupled to transistors in a second array of memory cells by a dielectric structure.

10. The memory device of claim 9, further comprising:
conductive pillars aligned with the dielectric structure in the channel direction;
wherein the conductive pillars are in contact with the dielectric structure.

11. The memory device of claim 7, wherein
along the bit line direction, each bit line connects to a first row of transistors in the first sub-array of memory cells and a corresponding second row of transistors in the second sub-array of memory cells.

12. The memory device of claim 11, wherein
along the bit line direction, capacitors in the first sub-array of memory cells and capacitors in the second sub-array of memory cells are separated by the isolation walls and contact structures located between the isolation walls.

13. The memory device of claim 12, further comprising:
semiconductor structures located between the first sub-array and the second sub-array; wherein
the semiconductor structures are covered by the isolation walls and the contact structures located between the isolation walls; and
the semiconductor structures are doped as either N-type or P-type.

14. The memory device of claim 7, wherein
a cross-section of the isolation walls on a first plane comprise a plurality of enclosed structures, the first plane is perpendicular to the channel direction; and
the contact structures are located outside the enclosed structures.

15. The memory device of claim 14, wherein
capacitors in the first sub-array of memory cells are surrounded by a first enclosed structure of the isolation walls; and
capacitors in the second sub-array of memory cells are surrounded by a second enclosed structure of the isolation walls.

16. A method of forming a memory device, comprising:
forming an array of transistors on a substrate;
forming bit lines coupled with the transistors in the array and extending in a bit line direction;
forming a stacked-structure on the array of transistors;
forming an array of holes throughout the stacked-structure; and
forming contact structures coupled with the bit lines in a first group of the holes and capacitors coupled with the transistors in a second group of the holes; wherein
the contact structures are isolated from the capacitors by isolation walls.

17. The method of claim 16, wherein forming a stacked-structure covering the array of transistors comprises:
forming a first dielectric layer on the array of transistors;
forming a second dielectric layer on the first dielectric layer; and
forming a third dielectric layer on the second dielectric layer; wherein
a material of the second dielectric layer is different from a material of the first dielectric layer or a material of the third dielectric layer.

18. The method of claim 17, wherein forming an array of holes throughout the stacked-structure comprises:
filling the array of holes with a sacrifice material different from the material of the first dielectric layer, the material of the second dielectric layer, and the material of the third dielectric layer.

19. The method of claim 18, wherein forming the contact structures and the capacitors comprises:
forming a first mask on the stacked-structure to cover the first group of holes and the second group of holes; and
removing the sacrifice material in a third group of holes that are exposed from openings on the first mask;
expanding the third group of holes by removing at least part of the second dielectric layer surrounding the third group of holes to punch the holes in the third group and form at least one isolation trench;
forming the isolation walls in the at least one isolation trench by depositing a dielectric material in the isolation trench, and the dielectric material is different from the material of the second dielectric layer;
forming the contact structures in the first group of holes by replacing the sacrifice material in the first group of holes with a conductive material, at least part of the contact structures being coupled with the bit lines;
forming first electrodes of the capacitors in the second group of holes by replacing the sacrifice material in the second group of holes with a conductive material; wherein the third group of holes comprises a plurality of enclosed structures;
the second group of holes are located within the plurality of enclosed structures;
the first group of holes are located between two adjacent enclosed structures;
the first electrodes are coupled with the transistors; and
the first electrodes are formed in a same fabrication process as the contact structures.

20. A memory device, comprising:
an array of memory cells in an array region surrounded by an enclosed isolation wall;
bit lines coupled with the memory cells in the array and extending in a bit line direction; and
contact structures located in a connecting region outside the enclosed isolation wall;
wherein
the array of memory cells comprises a plurality of transistors and a plurality of capacitors coupled with the transistors; and
the contact structures and the capacitors of the memory cells have a same size along a channel direction perpendicular to the bit line direction.
